(19) United States
(12) Patent Application Publication
(10) Pub. No.: US 2026/0322367 A1
(43) Pub. Date: Oct. 15, 2026

(54) Comparator With Multi-Phase Hysteresis

(71) Applicant: TEXAS INSTRUMENTS INCORPORATED, Dallas, TX (US)

(72) Inventors: Ho-Young Lee, San Jose, CA (US); Satoshi Sakurai, San Carlos, CA (US)

(21) Appl. No.: 19/222,684

(22) Filed: May 29, 2025

Related U.S. Application Data
(60) Provisional application No. 63/786,449, filed on Apr. 10, 2025.

(51) Int. Cl. H03K 5/24; H03F 1/02; H03F 3/45

(52) U.S. Cl. CPC H03K 5/2481; H03F 1/0255; H03F 3/45219; H03F 3/45273

(57) ABSTRACT

An apparatus includes a folded cascode amplifier having a first input, a second input, a first terminal, a second terminal, a first output, and a second output. A current generator circuit has a first output and a second output. The first output is coupled to the first terminal, and the second output is coupled to the second terminal. The current generator circuit is configured to: determine whether current above a threshold is flowing through the folded cascode amplifier; and in response to determining that current above the threshold is not flowing through the folded cascode amplifier, activate a first current into one of the first terminal or second terminal for a first time period, and then activate a second current into one of the first terminal or second terminal for a second time period.

### CROSS-REFERENCE TO RELATED APPLICATIONS

This application claims priority to U.S. Provisional Application No. 63/786,449, filed Apr. 10, 2025, which is hereby incorporated by reference.

### TECHNICAL FIELD

The present disclosure relates generally to an electronic system and method, and, in particular embodiments, to a comparator with multi-phase hysteresis.

### BACKGROUND

A comparator produces a digital output signal based on whether one input signal to the comparator is larger or smaller than another input signal. In some conditions, such as for a rapid increase in one of the input signals, parasitic capacitance within the comparator can result in a temporary state in which the output from the comparator may switch logic states without one input signal crossing the other input signal.

### SUMMARY

In one example, an apparatus includes a folded cascode amplifier having a first input, a second input, a first terminal, a second terminal, a first output, and a second output. A current generator circuit has a first output and a second output. The first output is coupled to the first terminal, and the second output is coupled to the second terminal. The current generator circuit is configured to: determine whether current above a threshold is flowing through the folded cascode amplifier; and in response to determining that current above the threshold is not flowing through the folded cascode amplifier, activate a first current into one of the first terminal or second terminal for a first time period, and then activate a second current into one of the first terminal or second terminal for a second time period.

In another example, an apparatus includes a folded cascode amplifier having a first input, a second input, a first terminal, and a second terminal. A first transistor has a first control terminal and a first transistor terminal. The first control terminal is coupled to the first input of the folded cascode amplifier. A second transistor has a second control terminal and a second transistor terminal. The second control terminal is coupled to the second input of the folded cascode amplifier. The second transistor terminal is coupled to the first transistor terminal. A reference voltage generator has an output. A current source circuit has a first current source circuit output and a second current source circuit output. The first and second current source circuit outputs are coupled to the first and second terminals, respectively. A comparator has a first comparator input, a second comparator input, and a comparator output. The first comparator input is coupled to the first transistor terminal and to the second transistor terminal. The second comparator input is coupled to the output of the reference voltage generator, and the comparator output is coupled to the current source circuit.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a schematic diagram of a comparator having a hysteresis current generator circuit, in accordance with an embodiment of the present disclosure;

FIG. 2 is a schematic diagram of a comparator having a hysteresis current generator circuit, in accordance with another embodiment of the present disclosure;

FIG. 3 is a schematic diagram of the hysteresis current generator circuit, in accordance with an embodiment of the present disclosure; and

FIGS. 4 and 5 include example waveforms of signals illustrating the operation of the hysteresis current generator circuit, in accordance with an embodiment of the present disclosure.

Corresponding numerals and symbols in different figures generally refer to corresponding parts unless otherwise indicated. The figures are drawn to clearly illustrate relevant aspects of preferred embodiments and are not necessarily drawn to scale.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The description below illustrates various specific details to provide an in-depth understanding of several example embodiments according to the description. The embodiments may be obtained without one or more of the specific details, or with other methods, components, materials and the like. In some cases, known structures, materials or operations are not shown or described in detail so as not to obscure the different aspects of the embodiments. References to “an embodiment” in this description indicate that a particular configuration, structure or feature described in relation to the embodiment is included in at least one embodiment. Consequently, phrases such as “in one embodiment” that may appear at different points of the present description do not necessarily refer exactly to the same embodiment. Furthermore, specific formations, structures or features may be combined in any appropriate manner in one or more embodiments.

Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events.

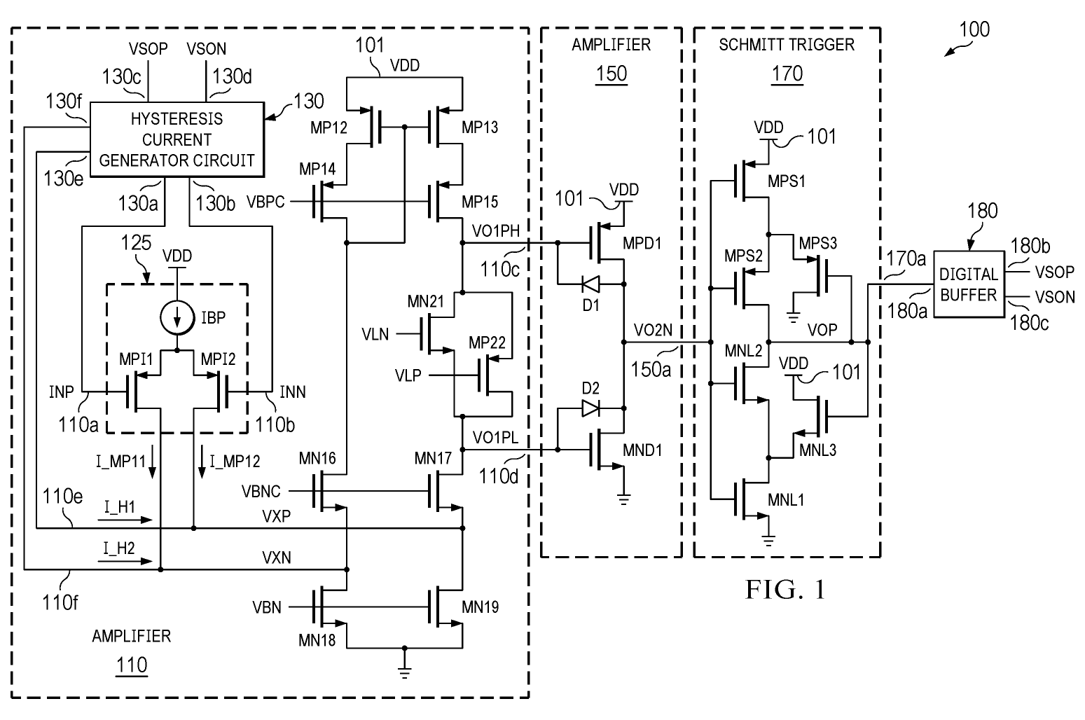

FIG. 1 is a schematic diagram of a comparator 100, according to an embodiment of the present disclosure. Comparator 100 includes amplifiers 110 and 150, a Schmitt trigger 170, and a buffer 180. In the example of FIG. 1, amplifier 110 is a folded cascode amplifier, and amplifier 150 is a class AB amplifier. Comparator 100 has inputs 110a and 110b and outputs 180b and 180c. The input signal to input 110a is INP, and the input signal to input 110b is INN. The output signals at outputs 180b and 180c include VSOP and VSON, respectively. Signal VSON is a logical inverse of signal VSOP. In one embodiment, comparator 100 asserts output signal VSOP to a logic high state and VSON to a logic low state in response to INP being greater than INN and asserts output signal VSOP to a logic low state and VSON to a logic high state in response to INP being smaller than INN.

Amplifier 110 includes a bias current source IBP and transistors MPI1, MPI2, MP12, MP13, MP14, MP15, MN21, MP22, MN16, MN17, MN18, and MN19, and a hysteresis current generator circuit 130. Transistors MPI1, MPI2, MP12, MP13, MP14, MP15, and MP22 are p-channel field effect transistors (PFETs), and transistors MN16, MN17, MN18, MN19, and MN21 are n-channel field effect transistors (NFETs). Transistors MPI1 and MPI2 represent an input pair 125 (also referred to as an input stage) for amplifier 110. The gates of transistors MPI1 and MPI2 are coupled to the comparator’s inputs 110a and 110b, respectively. Bias current source IBP is coupled to the sources of transistors MPI1 and MPI2 and provides bias current through those transistors. The drain of transistor MPI1 is coupled to the source of transistor MN16 and to the drain of transistor MN18. The drain of transistor MPI2 is coupled to the source of transistor MN17 and to the drain of transistor MN19. The sources of transistors MN18 and MN19 are coupled to ground. The gates of transistors MN16 and MN17 receive a bias voltage VBNC, and the gates of transistors MN18 and MN19 receive a bias voltage VBN.

The drains of transistors MN16 and MP14 are coupled together and to the gates of transistors MP12 and MP13. The source of transistor MP14 is coupled to the drain of transistor MP12. The sources of transistors MP12 and MP13 are coupled to a supply voltage terminal 101 and receive supply voltage VDD. The gates of transistors MP14 and MP15 receive a bias voltage VBPC. The drain of transistor MP13 is coupled to the source of transistor MP15. The drains of transistors MP15 and MN21 and the source of MP22 are coupled together and to an output 110c of amplifier 110. The gates of transistors MN21 and MP22 receive bias voltages VLN and VLP, respectively. The source of transistor MN21 and the drain of transistor MP22 are coupled to the drain of transistor MN17 and to an output 110d of amplifier 110. The signals at outputs 110c and 110d of amplifier 110 are VO1PH and VO1PL, respectively.

Hysteresis current generator circuit 130 has inputs 130a, 130b, 130c, and 130d and outputs 130e and 130f. Inputs 130a and 130b are coupled to inputs 110a and 110b, respectively, of comparator 100. Inputs 130c and 130d are coupled to outputs 180b (VSOP) and 180c (VSO) of comparator 100. Output 130d of hysteresis current generator circuit 130 is coupled to terminal 110e, and output 130e is coupled to terminal 110f.

As noted above, amplifier 110 in the example of FIG. 1 is a folded cascode amplifier. Bias current flows through the serial string of transistors MP12, MP14, MN16, and MN18 (referred to herein as the “lefthand branch” of amplifier 110). Similarly, bias current flows through the serial string of transistors MP13, MP15, MN17, and MN19 and through the transistor pair MN21 and MP22 (the “righthand branch”). Transistor pair MN21 and MP22 provide a direct current (DC)-level-shifted output (VO1PH, VO1PL) of amplifier 110. However, a difference in voltage between input signals INP and INN results in one of currents I_MP11 and I_MP12 being larger than the other. For example, if input signal INN is smaller than input signal INP, then current I_MP12 will be larger than current I_MP11. Conversely, if input signal INP is smaller than input signal INN, then current I_MP11 will be larger than current I_MP12. Current I_MP11 is injected into the drain of transistor MN18 and current I_MP12 is injected into the drain of transistor MN19.

Because of the fixed bias voltage VBN at the gates of transistors MN18 and MN19, the currents through transistors MN18 and MN19 are fixed. If current I_MP12 is larger than current I_MP11 (e.g., as a result of INP being larger than INN), the current through transistor MN17 will be smaller than the current through transistor MN16. The current through transistor MN16 flows through transistors MP12 and MP14 and is mirrored through transistor MP13. The larger current through transistor MN16 (compared to MN17) flows through transistor MP15 as well. Because the current from VDD through transistors MP13 and MP15 is larger than the current through transistors MN17 and MN19 to ground, both the outputs of the first amplifier (VO1PH, VO1PL) become higher than the DC bias voltages. By contrast, the outputs VO1PH and VO1PL decrease if current I_MP11 is larger than current I_MP12.

Amplifier 150 includes transistors MPD1 and MND1 and diodes D1 and D2. Transistor MPD1 is a PFET, and transistor MND1 is an NFET. The source of transistor MPD1 is coupled to the supply voltage terminal 101, and the source of transistor MND1 is coupled to ground. The drains of transistors MPD1 and MND1 are coupled together and to an output 150a of amplifier 150. The signal at the output 150a of amplifier 150 is signal VO2N. The anode of diode D1 is coupled to the drain of transistor MPD1, and the cathode of transistor D1 is coupled to the gate of transistor MPD1. The output 110c of amplifier 110 is coupled to the gate of transistor MPD1. The cathode of diode D2 is coupled to the drain of transistor MND1, and the anode of transistor D2 is coupled to the gate of transistor MND1. The output 110d of amplifier 110 is coupled to the gate of transistor MND1. Transistors MPD1 and MND1 operate in the linear region. Both of transistors MPD1 and MND1 generally remain on continuously during operation of comparator 100.

Schmitt trigger 170 includes transistors MPS1, MPS2, MPS3, MNL1, MNL2, and MNL3. Transistors MPS1, MPS2, and MPS3 are PFETs, and transistors MNL1, MNL2, and MNL3 are NFETs. Transistors MPS1 and MPS2 are coupled in series between the supply voltage terminal 101 and an output 170a of the Schmitt trigger. Transistors MNL2 and MNL1 are coupled in series between output 170a of and ground. The source of a transistor MPS3 is coupled to the drain of transistor MPS1 and to the source of transistor MPS2. The drain of transistor MPS3 is coupled to ground. The output 170a is coupled to the gates of transistor MPS3 and MNL3. The source of transistor MNL3 is coupled to the drain of transistor MNL1 and to the source of transistor MNL2. The drain of transistor MNL3 is coupled to the supply voltage terminal 101. The signal at the output 170a of Schmitt trigger 170 is signal VOP. Schmitt trigger 170 functions to force signal VOP to either approximately VDD or ground based on whether the output signal VO2N from amplifier 150 is above or below a threshold of the Schmitt trigger.

The output 170a of Schmitt trigger is coupled to an input 180a of digital buffer 180. Digital buffer may provide voltage level shifting of the output signal from Schmitt trigger 170 to a different voltage domain. Output signals VSOP and VSON are provided at digital buffer’s outputs 180c and 180d, respectively.

When input signal (e.g., INN) is at a higher level such as close to VDD, a second input signal (e.g., INP) is at a lower level such as close to ground, and the second input signal rapidly increases towards VDD, for example, with INN close to VDD, little or no current may flow through transistor MPI2. As INP rapidly increases, the voltage on the sources of transistors MPI1 and MPI2 also increases. However, due to the parasitic capacitance on the sources of transistors MPI1 and MPI2 (e.g., the gate-to-source capacitance and the drain-to-source capacitance), the voltage on the sources of transistors of transistors MPI1 and MPI2 does not rise as rapidly as the gate voltage of transistor MPI1 may rise. In response to a slower slew rate of the voltage on the source of transistor MPI1 than the slew rate of input signal INP, most or all of the tail current from bias current source IBP is used to charge the parasitic capacitance on the source of transistor MPI1 and little or no current flows through transistor MPI1. In this state, currents I_MP11 and I_MP12 may be 0 amperes—current I_MP11 is 0 amperes because of the slower rise in its source voltage relative to its gate voltage and current I_MP12 is 0 amperes because input signal INN is already at a higher level. Eventually, the source of transistor MPI1 is charged to a level high enough that current I_MP11 may again flow through transistor MPI1. The period of time during which no current flows through transistors MPI1 or MPI2 may be referred to as a “current dead zone.”

If neither current I_MP11 nor I_MP12 is present, then no differential current from transistors MPI1 and MPI2 may be provided to the drains of transistors MN18 and MN19. As a result of the cessation of the differential current, the output state of comparator 100 may be indeterminate. A current glitch may occur for current I_MP12 during the current dead zone as a result of a voltage coupling between transistors MPI1 and MPI2. A current glitch for current I_MP12 may undesirably cause the comparator’s output signal VOP to change logic state even though input signal INP has not crossed input signal INN. Even when no current glitch is present for current I_MPI12, device mismatches between transistors MP12-MP15 and MN16-MN19 may also result in the output signal VOP from comparator 100 changing logic state.

In some embodiments, hysteresis current generator circuit 130 advantageously detects the condition in which both currents I_MP11 and I_MP12 cease flowing (the current dead zone). In response to detecting the occurrence of a current dead zone, hysteresis current generator circuit 130 generates a differential hysteresis current IH1-IH2 (also referred to as a hysteresis current) into terminals 110e and 110f based on the output signal VOP. For example, responsive to output signal VOP being logic high, the differential hysteresis current I_H1-IH2 may be positive, and responsive to output signal VOP being logic low, the differential current may be negative. The differential hysteresis current from hysteresis current generator circuit 130 advantageously may prevent the comparator’s output signal VOP from changing logic state.

In accordance with some embodiments, hysteresis current generator circuit 130 may generate a multi-phase hysteresis current. In one such embodiment, the multi-phase hysteresis current is a two-phase hysteresis current including an initial higher hysteresis current for a first time period followed (e.g., immediately followed) by a subsequent lower hysteresis current for a second time period. In one embodiment, the second time period is longer than the first time period, and the combined first and second time periods may be slightly longer than the current dead zone. The higher hysteresis current may prevent the output signal VOP of comparator 100 from changing logic state in the event of a current glitch on either of currents I_MPI1 and I_MPI2. The length of time of the first time period may be determined by, for example, simulation or testing. The subsequent lower hysteresis current advantageously allows the comparator 100 to return to normal operation faster than if the higher hysteresis current was continued during the second time period. The length of the current dead zone may be determined through simulation or testing. An example is provided below of an implementation of hysteresis current generator circuit 130.

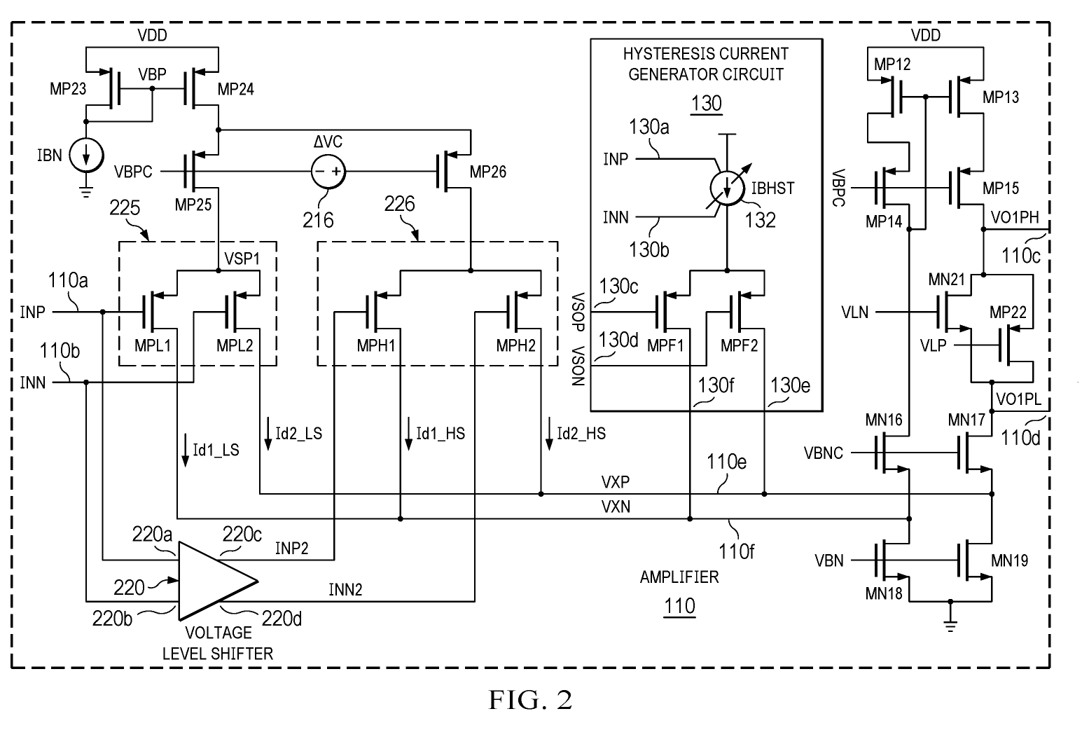

FIG. 2 is a schematic diagram of another embodiment of amplifier 110, according to an embodiment of the present disclosure. The embodiment of amplifier 110 in FIG. 2 is similar to the embodiment of amplifier 110 in FIG. 1 with several differences. For example, rather than one input pair 125 as in FIG. 1 (e.g., transistors MPI1 and MPI2), the input stage for amplifier 110 in FIG. 2 as two transistor input pairs 225 and 226. Input pair 225 includes transistors MPL1 and MPL2, and input pair 226 includes transistors MPH1 and MPH2. The size of transistors MPL1 and MPL2 may be approximately the same. Similarly, the size of transistors MPH1 and MPH2 may be approximately the same. However, the size of transistors MPL1 and MPL2 may be the same as or a different size than the size of transistors MPH1 and MPH2. The drains of transistors MPL2 and MPH2 are coupled to terminal 110e, and the drains of transistors MPL1 and MPH1 are coupled to terminal 110f. The currents through transistors MPL1 and MPL2 are currents Id1_LS and Id2_LS, respectively. The currents through transistors MPH1 and MPH2 are currents Id1_HS and Id2_HS, respectively. Amplifier 110 in FIG. 2 also includes transistors MP23-MP26, which provide bias current to input pairs 225 and 226. The sources of transistors MPL1 and MPL2 are coupled together and to the drain of transistor MP25. The sources of transistors MPH1 and MPH2 are coupled together and to the drain of transistor MP26. Bias voltage VBPC is provided to the gate of transistor MP25. A voltage source circuit 216 (ΔVC) is coupled between the gates of transistors MP25 and MP26. The gate of transistor MP26 receives a voltage that is ΔVC larger than bias voltage VBPC. Transistors MP23 and MP24 are coupled together to form a current a current mirror to mirror current IBN through transistor MP24.

Input signals INP and INN are provided to the gates of transistors MPL1 and MPL2, respectively. Input signals INP and INN are also provided to inputs 220a and 220b of voltage level shifter 220. Outputs 220c and 220d of voltage level shifter 220 are coupled to the gates of transistors MPH1 and MPH2, respectively, and receive signals INP2 and INN2. Voltage level shifter 220 level shifts downward the voltages of input signals INP and INN, for example, by approximately 1V.

By including two input pairs 225 and 226, comparator 100 may be operative over a common mode voltage range from approximately 0V (ground) to approximately VDD. At a lower range of common mode voltages, current from transistor MP24 may flow through transistor MP25 and to input pair 225. At a higher range of common mode voltages, current from transistor MP24 may flow through transistor MP26 and to input pair 226. Accordingly, during operation, the bias current from transistor MP24 flows through either input pair 225 as currents Id1_LS and Id2_LS or input pair 226 as currents Id1_HS and Id2_HS. As described above, if one input signal (e.g., INN) is at a high level (e.g., close to VDD), and the other input signal (INP) rises sharply from near ground to close to VDD, most or all of the bias current from transistor MP24 charges the parasitic capacitance on the sources of transistors MPL1 and MPL2. During the time that the parasitic capacitance on transistors MPL1 and MPL2 is charging, bias current may not flow through either input pair 225 or 226 resulting in a current dead zone. During the current dead zone, a glitch may occur for any of the current flowing the corresponding input pair into terminals 110e or 110f potentially resulting in output signal from comparator changing logic state. Further, device mismatches among transistors MP12-MP15 and MN16-MN19 may also inadvertently result in the comparator’s output changing logic state.

In some embodiments, hysteresis current generator circuit 130 addresses the current dead zone behavior. For example, in the embodiment of FIG. 2, hysteresis current generator circuit 130 includes a current source 132 and transistors MPF1 and MPF2. The sources of transistors MPF1 and MPF2 are coupled together and to current source 132. Current source 132 also receives the input signals INP and INN. The drain of transistor MPF1 is coupled to terminal 110f, and the drain of transistor MPF2 is coupled to terminal 110e. The gate of transistor MPF1 receives output signal VSOP, and the gate of transistor MPF2 receives output signal VSON.

In one embodiment, current source 132 detects when a current dead zone has occurred and responds by generating a two-phase hysteresis current (IBHST). The two-phase hysteresis current IBHST flows through transistors MPF1 and MPF2 based on output signals VSOP and VSON. For example, if VSOP is smaller than VSON, more of the two-phase hysteresis current IBHST flows through transistor MPF1 than transistor MPF2. Conversely, if VSOP is larger than VSON, more of the two-phase hysteresis current IBHST flows through transistor MPF2 than transistor MPF1. The addition of a two-phase hysteresis current into terminals 110e and 110f helps to prevent the comparator 100 from tripping the logic state of its output VSOP-VSON during a current dead zone, as described above.

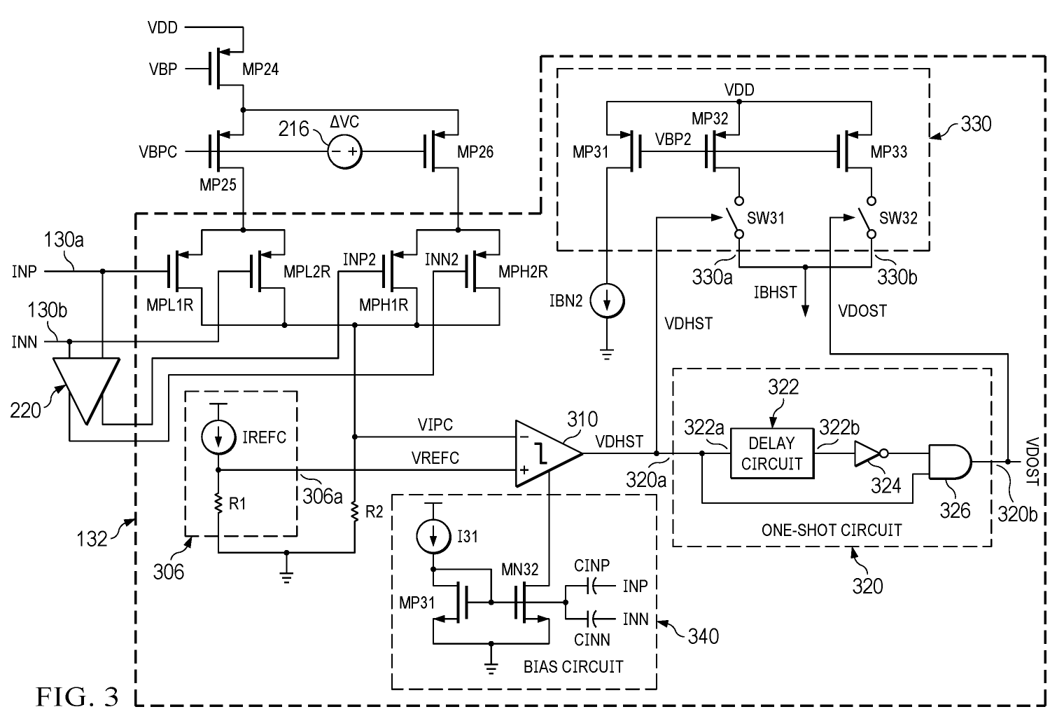

FIG. 3 is a circuit schematic illustrating an embodiment of current source 132, which may generate a two-phase hysteresis current IBHST, according to an embodiment of the present disclosure. In the embodiment of FIG. 3, current source 132 is coupled to transistors MP25 an MP26 and to voltage level shifter 220. Current source 132 includes transistors MPL1R, MPL2R, MPH1R, and MPH2R, comparator 310, a one-shot circuit 320, a source circuit 339, bias circuit 340, resistor R2 and voltage reference generator 306. Transistors MPL1R, MPL2R, MPH1R, and MPH2R are PFETs in the embodiment of FIG. 3. Transistors MPL1R and MPL2R may be of the same size but smaller than the size of transistors MPL1 and MPL2. Similarly, transistors MPH1R and MPH2R may be of the same size but smaller than the size of transistors MPH1 and MPH2. The sources of transistors MPL1R and MPL2R are coupled together and to the drain of transistor MP25. The sources of transistors MPH1R and MPH2R are coupled together and to the drain of transistor MP26. The gates of transistors MPL1R and MPL2R receive input signals INP and INN, respectively. The gates of transistors MPH1R and MPH2R receive signals INP2 and INN2, respectively, from voltage level shifter 220.

The drains of transistors MPL1R, MPL2R, MPH1R, and MPH2R are coupled together and to the negative (-) input of comparator 310. Resistor R2 is coupled between the comparator’s negative input and ground. Current from any one or more of transistors MPL1R, MPL2R, MPH1R, or MPH2R flows through resistor R2 thereby generating a voltage VIPC at the negative input of comparator 310. In the absence of current from any of transistors MPL1R, MPL2R, MPH1R, or MPH2R, the voltage VIPC at the negative input of comparator 310 is 0V.

In the embodiment of FIG. 3, voltage reference generator 306 includes a current source IREFC coupled to a resistor R1. Resistor R1 is also coupled to the positive (+) input of comparator 310. Current IREFC flows through resistor R1 thereby generating a reference voltage VREFC. Comparator 310 compares VIPC to VREFC and generates a signal VDHST at its output based on the relative comparison of VIPC to VREFC. In one embodiment of FIG. 3, comparator 310 asserts a positive pulse for signal VDHST in response to VIPC being smaller than VREFC, which may be indicative of a current dead zone condition. The width of the pulse is at least equal to the predicted/anticipated length of the current dead zone. In some embodiments, the pulse width for signal VDHST may be slightly larger than the current dead zone, e.g., by a 10% margin.

In some embodiments, one-shot circuit 320 has an input 320a and an output 320b. Input 320a is coupled to the output of comparator 310. In the embodiment of FIG. 3, one-shot circuit 320 includes a delay circuit 322, an inverter 324, and an AND gate 326. Input 320a of one-shot circuit 320 is coupled to an input 322a of delay circuit 322. Delay circuit 322 generates a signal at its output 322b that is a delayed version of the positive pulse for signal VDHST at its input 322a. In one embodiment, the time delay implemented by delay circuit 322 may be smaller than the predicted/anticipated length of the current dead zone. In one embodiment, the time delay implemented by delay circuit 322 may be slightly larger than that portion of the current dead zone in which a glitch on one of the currents I_MP1 or I_MP2 (FIG. 1) or Id1_LS, Id2_LS, Id1_HS, or Id2_HS (FIG. 2) may occur, for example, as determined through simulation or testing. The output 322b of delay circuit 322 is coupled to the input of inverter 324. The output of inverter 324 is coupled to an input 326a of AND gate 326. The other input 326b of AND gate 326 is coupled to input 320a of one-shot circuit 320.

In some embodiments, inverter 324 logically inverts the delayed version of signal VDHST with non-delayed signal VDHST thereby generating a signal VDOST at the output of 320b of one-shot circuit 320 that is a pulse having a rising edge coincident with the rising edge of signal VDHST and a falling edge coincident with the time delay implemented by delay circuit 322. The resulting pulse for signal VDOST starts at the beginning of the current dead zone and ends at or after that portion of the current dead zone in which a current glitch may occur.

In some embodiments, current source circuit 329 includes a bias current IBN2, a current mirror 330, and switches SW31 and SW32. Current mirror 330 includes transistors MP31, MP32, and MP33. Current mirror 330 has current mirror outputs 330a and 330b. Bias current IBN2 is coupled to the drain of transistor MP31. Bias current IBN2 flows through transistor MP31. The gates of transistors MP31-MP33 are coupled together and to the drain of transistor MP31. The current mirror ratio between transistors MP32 and MP31 may differ from the current mirror ratio between transistors MP33 and MP31. For example, the current mirror ratio between transistors MP33 and MP31 may be larger than the current mirror ratio between transistors MP32 and MP31. The drains of transistors MP32 and MP33 are coupled to current mirror outputs 330a and 330b, respectively. Switch SW31 (e.g., a FET) is coupled between the current mirror output 330a and the sources of transistors MPF1 and MPF2 (FIG. 2). Switch SW32 (e.g., a FET) is coupled between the current mirror output 330b and the sources of transistors MPF1 and MPF2.

The output of comparator 310 is coupled to a control terminal (e.g., gate) of switch SW31. Accordingly, switch SW31 is opened and closed responsive to the logic state of signal VDHST. For example, switch SW31 is closed in response to signal VDHST being logic high and open in response to signal VDHST being logic low. The output 320b of one-shot circuit 320 is coupled to a control terminal (e.g., gate) of switch SW32. Accordingly, switch SW32 is opened and closed responsive to the logic state of signal VDOST. For example, switch SW32 is closed in response to signal VDOST being logic high and open in response to signal VDOST being logic low. A bias current IBN2 flows through transistor MP31 and is mirrored by either transistor MP32 or MP33 based on which of switches SW31 or SW32 is closed. Because of the difference in current mirror ratios, two-phase hysteresis current IBHST may have a larger amplitude when both signals VDHST and VDOST are logic high (which occurs at the beginning of the detected current dead zone) and then a lower amplitude when signal VDOST returns to a logic low level following the delay time period implemented by delay circuit 322 while the detected current dead zone persists.

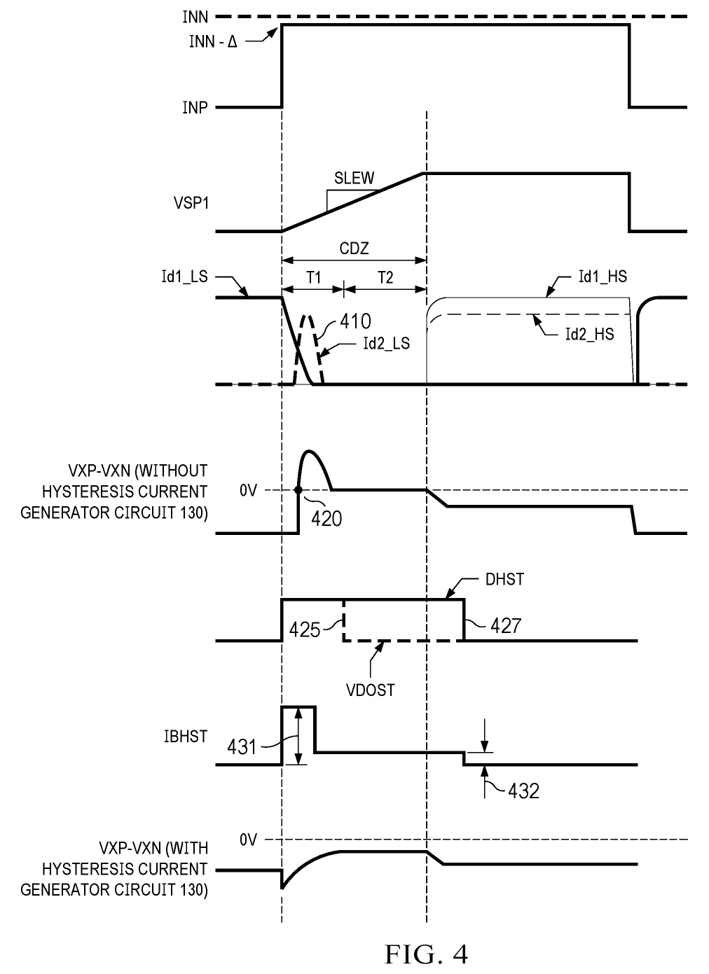

FIG. 4 is a diagram including waveforms illustrating the operation of hysteresis current generator circuit 130, according to an embodiment of the present disclosure. Waveforms for input signals INN and INP, voltage VSP1, currents Id1_LS and Id2_LS, voltage difference VXP-VXN (without hysteresis current generator circuit 130), signals VDHST and VDOST, hysteresis current IBHST, and voltage difference VXP-VXN (with hysteresis current generator circuit 130). In the example of FIG. 4, input signal INN is at a high level (e.g., close to VDD) and input signal INP rises sharply from a low level to close to but less than INN. The voltage VSP1 rises more slowly as bias current charges the parasitic capacitances on the sources of, for example, transistors MPL1 and MPL2. While voltage VSP1 rises, a current dead zone (CDZ) occurs when input pairs 225 and 226 do not conduct any bias current from transistor MP24. During the current dead zone, current Id1_LS falls to 0 amperes as a result of INP rising, and current ID2_LS is at and remains 0 amperes as a result of INN already being at a high level. As described above, a current glitch 410 may occur during an initial part of the current dead zone. If the current glitch is high enough, the output of amplifier 110 may change polarity from negative to positive as indicated at time point 420. A change in the polarity of VXP-VXN may cause the output signal VSOP from comparator 100 to change polarity as well.

As the current through the transistors of input pairs 225/226 falls to 0 amperes, comparator 310 responds by generating a pulse for signal VDHST. Further, one-shot circuit 320 responds to the rising edge of the pulse of signal VDHST by generating a shorter duration pulse for signal VDOST. Switches SW31 and SW32 are closed when both signals VDHST and VDOST are logic high and a higher level 431 of hysteresis current IBHST is generated to help ensure that the output VXP-VXN of amplifier 110 does not change polarity despite the possible occurrence of a current glitch, e.g., current glitch 410. Then, when the falling edge 425 of signal VDOST occurs, switch SW32 opens and the hysteresis current IBHST falls to a lower level 432 until the falling edge 427 of signal VDHST occurs. The two-phase hysteresis current injected into terminals 110e and 110f causes the output of amplifier 110, VO1PH-VO1PL to remain negative throughout the entire current dead zone. Comparator 100 also returns to normal operation in which it reacts to the relative difference between input signals INP and INN quickly due to the lower level 432 of hysteresis current IBHST compared to the response of comparator 100 if hysteresis current IBHST had only a signal, higher level 431 throughout the entire current dead zone.

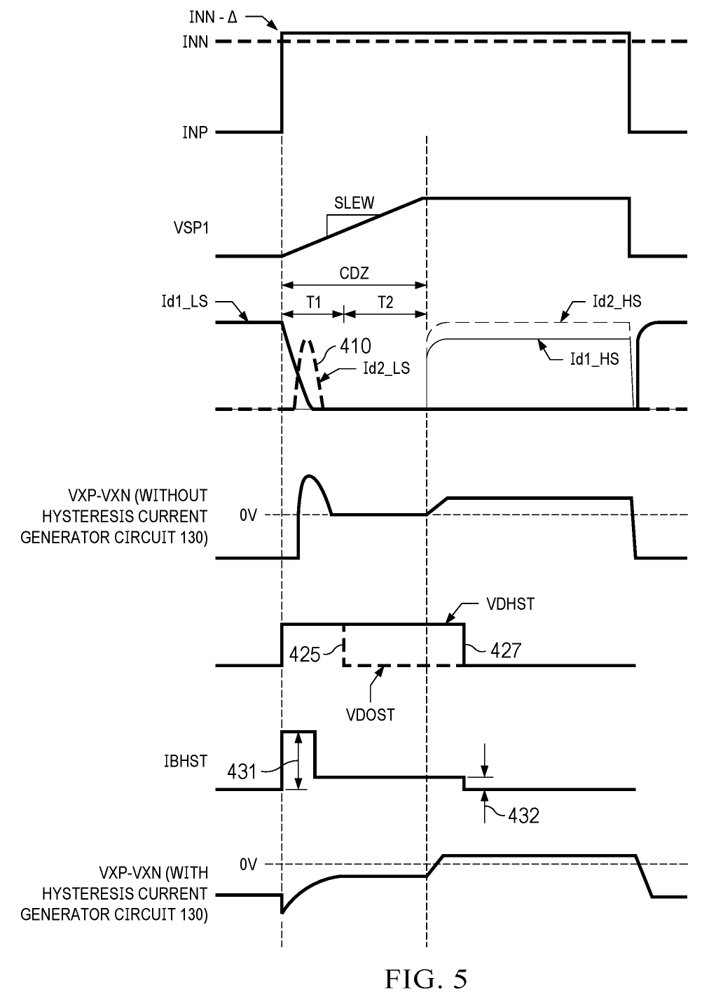

In the waveform example of FIG. 5, input signal INP also rapidly increases but increases to be larger than input signal INN. In some embodiments, the response of the hysteresis current generator circuit 130 is the same as that described above. For example, in some embodiments, hysteresis current generator circuit 130 generates the two-phase hysteresis current IBHST as described above. The lower level 432 of hysteresis current IBHST persists until the falling edge 427. Because of the lower level 432 of the hysteresis current IBHST, comparator 100 advantageously is able to react more quickly to input signal INP being larger than input signal INN when the two-phase hysteresis current IBHST returns to 0 amperes than would have been the case if the hysteresis current was implemented with only a single, higher current amplitude.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT – e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor’s control input and its current terminals. In the context of a FET, the control input is the gate, and the current terminals are the drain and source. In the context of a BJT, the control input is the base, and the current terminals are the collector and emitter. The gate, source, and drain of a FET and base, collector, and emitter of a BJT are terminals of the transistor.

Circuits described herein may be reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description may include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/- 10 percent of that parameter or, if the parameter is zero, a reasonable range of values around zero.

Example embodiments of the present disclosure are summarized here. Other embodiments can also be understood from the entirety of the specification and the claims filed herein.

Example 1. An apparatus including: a folded cascode amplifier having a first input, a second input, a first terminal, a second terminal, a first output, and a second output; and a current generator circuit having a first output and a second output, the first output coupled to the first terminal, and the second output coupled to the second terminal, the current generator circuit configured to: determine whether current above a threshold is flowing through the folded cascode amplifier; and in response to determining that current above the threshold is not flowing through the folded cascode amplifier, activate a first current into one of the first terminal or second terminal for a first time period, and then activate a second current into one of the first terminal or second terminal for a second time period.

Example 2. The apparatus of example 1, where the first time period is shorter than the second time period.

Example 3. The apparatus of one of examples 1 or 2, where the folded cascode amplifier has an input stage, the input stage including: a first transistor having a first control terminal and a first transistor terminal, the first transistor terminal coupled to the first terminal; and a second transistor having a second control terminal and a second transistor terminal, the second transistor terminal coupled to the second terminal.

Example 4. The apparatus of one of examples 1 to 3, where the input stage further includes: a third transistor having a third control terminal and a third transistor terminal, the third transistor terminal coupled to the first terminal; and a fourth transistor having a fourth control terminal and a fourth transistor terminal, the fourth transistor terminal coupled to the second terminal.

Example 5. The apparatus of one of examples 1 to 4, where the current generator circuit is configured to determine whether the current is flowing through the input stage of the folded cascode amplifier.

Example 6. The apparatus of one of examples 1 to 5, where the current generator circuit includes: a third transistor having a third control terminal and a third transistor terminal, the third control terminal coupled to the first control terminal; a fourth transistor having a fourth control terminal and a fourth transistor terminal, the fourth control terminal coupled to the second control terminal, and the fourth transistor terminal coupled to the third transistor terminal; and a comparator having a first comparator input coupled to the third and fourth transistor terminals and having a second comparator input coupled to a reference voltage generator.

Example 7. The apparatus of one of examples 1 to 6, where the comparator is configured to generate a pulse responsive to a voltage at the first comparator input being smaller than a voltage at the second comparator input.

Example 8. The apparatus of one of examples 1 to 7, where the comparator has an output, and the current generator circuit includes a one-shot circuit having an input coupled to the output of the comparator.

Example 9. The apparatus of one of examples 1 to 8, where the comparator is configured to generate a first pulse having a first pulse width, the one-shot circuit configured to generate a second pulse having a second pulse width, the first pulse width being longer than the second pulse width.

Example 10. The apparatus of one of examples 1 to 9, where the current generator circuit includes: a current mirror having a first current mirror output and a second current mirror output, the current mirror configured to generate the first current at the first current mirror output and to generate the second current at the second current mirror output.

Example 11. The apparatus of one of examples 1 to 10, where the current generator circuit is configured to select the first current mirror output for the first time period and then select the second current mirror output for the second time period.

Example 12. The apparatus of one of examples 1 to 11, where the second time period immediately follows the first time period.

Example 13. An apparatus including: a folded cascode amplifier having a first input, a second input, a first terminal, and a second terminal; a first transistor having a first control terminal and a first transistor terminal, the first control terminal coupled to the first input of the folded cascode amplifier; a second transistor having a second control terminal and a second transistor terminal, the second control terminal coupled to the second input of the folded cascode amplifier, the second transistor terminal coupled to the first transistor terminal; a reference voltage generator having an output; a current source circuit having a first current source circuit output and a second current source circuit output, the first and second current source circuit outputs coupled to the first and second terminals, respectively; and a comparator having a first comparator input, a second comparator input, and a comparator output, the first comparator input coupled to the first transistor terminal and to the second transistor terminal, the second comparator input coupled to the output of the reference voltage generator, and the comparator output coupled to the current source circuit.

Example 14. The apparatus of example 13, further including: a third transistor having a third control terminal and a third transistor terminal coupled to the first and second transistor terminals; and a fourth transistor having a fourth control terminal and a fourth transistor terminal, the fourth transistor terminal coupled to the first, second, and third transistor terminals.

Example 15. The apparatus of one of examples 13 or 14, further including a voltage level shifter having first and second voltage level shifter inputs and first and second voltage level shifter outputs, the first voltage level shifter input coupled to the first control terminal, the second voltage level shifter input coupled to the second control terminal, the first voltage level shifter output coupled to the third control terminal, and the second voltage level shifter output coupled to the fourth control terminal.

Example 16. The apparatus of one of examples 13 to 15, further including a resistor coupled between the first comparator input and a ground terminal.

Example 17. The apparatus of one of examples 13 to 16, further including a bias circuit coupled to the comparator, the bias circuit configured to provide a bias current for the comparator responsive to a first voltage at the first control terminal and a second voltage at the second control terminal.

Example 18. The apparatus of one of examples 13 to 17, further including: a current mirror having a bias circuit terminal and an output, the output coupled to the comparator; a first capacitor having first and second capacitor terminals, the first capacitor terminal coupled to the first control terminal, and the second capacitor terminal coupled to the bias circuit terminal; and a second capacitor having third and fourth capacitor terminals, the third capacitor terminal coupled to the second control terminal, and the fourth capacitor terminal coupled to the bias circuit terminal.

Example 19. The apparatus of one of examples 13 to 18, where the comparator has an output, and the apparatus further includes a one-shot circuit having an input coupled to the output of the comparator.

Example 20. The apparatus of one of examples 13 to 19, where the one-shot circuit has an output, and the current source circuit includes: a current mirror having a first current mirror output and a second current mirror output; a first switch coupled to the first current mirror output, the first switch having a first switch control input coupled to the output of the comparator; and a second switch coupled to the second current mirror output, the second switch having a second switch control input coupled to the output of the one-shot circuit.

Example 21. The apparatus of one of examples 13 to 20, where the comparator is configured to generate a first pulse having a first pulse width, the one-shot circuit is configured to generate a second pulse having a second pulse width, the first pulse width longer than the second pulse width.

Example 22. The apparatus of one of examples 13 to 21, where the current mirror is configured to provide a first current at the first current mirror output and a second current at the second current mirror output, the first current having a different amplitude than the second current.

While this disclosure has been described with reference to illustrative embodiments, this description is not limiting. Various modifications and combinations of the illustrative embodiments, as well as other embodiments, will be apparent to persons skilled in the art upon reference to the description.

What is claimed is:

1. An apparatus comprising:
a folded cascode amplifier having a first input, a second input, a first terminal, a second terminal, a first output, and a second output; and
a current generator circuit having a first output and a second output, the first output coupled to the first terminal, and the second output coupled to the second terminal, the current generator circuit configured to:
determine whether current above a threshold is flowing through the folded cascode amplifier; and
in response to determining that current above the threshold is not flowing through the folded cascode amplifier, activate a first current into one of the first terminal or second terminal for a first time period, and then activate a second current into one of the first terminal or second terminal for a second time period.

2. The apparatus of claim 1, wherein the first time period is shorter than the second time period.

3. The apparatus of claim 1, wherein the folded cascode amplifier has an input stage, the input stage including:
a first transistor having a first control terminal and a first transistor terminal, the first transistor terminal coupled to the first terminal; and
a second transistor having a second control terminal and a second transistor terminal, the second transistor terminal coupled to the second terminal.

4. The apparatus of claim 3, wherein the input stage further includes:
a third transistor having a third control terminal and a third transistor terminal, the third transistor terminal coupled to the first terminal; and
a fourth transistor having a fourth control terminal and a fourth transistor terminal, the fourth transistor terminal coupled to the second terminal.

5. The apparatus of claim 3, wherein the current generator circuit is configured to determine whether the current is flowing through the input stage of the folded cascode amplifier.

6. The apparatus of claim 3, wherein the current generator circuit comprises:
a third transistor having a third control terminal and a third transistor terminal, the third control terminal coupled to the first control terminal;
a fourth transistor having a fourth control terminal and a fourth transistor terminal, the fourth control terminal coupled to the second control terminal, and the fourth transistor terminal coupled to the third transistor terminal; and
a comparator having a first comparator input coupled to the third and fourth transistor terminals and having a second comparator input coupled to a reference voltage generator.

7. The apparatus of claim 6, wherein the comparator is configured to generate a pulse responsive to a voltage at the first comparator input being smaller than a voltage at the second comparator input.

8. The apparatus of claim 6, wherein the comparator has an output, and the current generator circuit comprises a one-shot circuit having an input coupled to the output of the comparator.

9. The apparatus of claim 8, wherein the comparator is configured to generate a first pulse having a first pulse width, the one-shot circuit configured to generate a second pulse having a second pulse width, the first pulse width being longer than the second pulse width.

10. The apparatus of claim 1, wherein the current generator circuit comprises:
a current mirror having a first current mirror output and a second current mirror output, the current mirror configured to generate the first current at the first current mirror output and to generate the second current at the second current mirror output.

11. The apparatus of claim 10, wherein the current generator circuit is configured to select the first current mirror output for the first time period and then select the second current mirror output for the second time period.

12. The apparatus of claim 1, wherein the second time period immediately follows the first time period.

13. An apparatus comprising:
a folded cascode amplifier having a first input, a second input, a first terminal, and a second terminal;
a first transistor having a first control terminal and a first transistor terminal, the first control terminal coupled to the first input of the folded cascode amplifier;
a second transistor having a second control terminal and a second transistor terminal, the second control terminal coupled to the second input of the folded cascode amplifier, the second transistor terminal coupled to the first transistor terminal;
a reference voltage generator having an output;
a current source circuit having a first current source circuit output and a second current source circuit output, the first and second current source circuit outputs coupled to the first and second terminals, respectively; and
a comparator having a first comparator input, a second comparator input, and a comparator output, the first comparator input coupled to the first transistor terminal and to the second transistor terminal, the second comparator input coupled to the output of the reference voltage generator, and the comparator output coupled to the current source circuit.

14. The apparatus of claim 13, further comprising:
a third transistor having a third control terminal and a third transistor terminal coupled to the first and second transistor terminals; and
a fourth transistor having a fourth control terminal and a fourth transistor terminal, the fourth transistor terminal coupled to the first, second, and third transistor terminals.

15. The apparatus of claim 14, further comprising a voltage level shifter having first and second voltage level shifter inputs and first and second voltage level shifter outputs, the first voltage level shifter input coupled to the first control terminal, the second voltage level shifter input coupled to the second control terminal, the first voltage level shifter output coupled to the third control terminal, and the second voltage level shifter output coupled to the fourth control terminal.

16. The apparatus of claim 13, further comprising a resistor coupled between the first comparator input and a ground terminal.

17. The apparatus of claim 13, further comprising a bias circuit coupled to the comparator, the bias circuit configured to provide a bias current for the comparator responsive to a first voltage at the first control terminal and a second voltage at the second control terminal.

18. The apparatus of claim 13, further comprising:
a current mirror having a bias circuit terminal and an output, the output coupled to the comparator;
a first capacitor having first and second capacitor terminals, the first capacitor terminal coupled to the first control terminal, and the second capacitor terminal coupled to the bias circuit terminal; and
a second capacitor having third and fourth capacitor terminals, the third capacitor terminal coupled to the second control terminal, and the fourth capacitor terminal coupled to the bias circuit terminal.

19. The apparatus of claim 13, wherein the comparator has an output, and the apparatus further comprises a one-shot circuit having an input coupled to the output of the comparator.

20. The apparatus of claim 19, wherein the one-shot circuit has an output, and the current source circuit comprises:
a current mirror having a first current mirror output and a second current mirror output;
a first switch coupled to the first current mirror output, the first switch having a first switch control input coupled to the output of the comparator; and
a second switch coupled to the second current mirror output, the second switch having a second switch control input coupled to the output of the one-shot circuit.

21. The apparatus of claim 20, wherein the comparator is configured to generate a first pulse having a first pulse width, the one-shot circuit is configured to generate a second pulse having a second pulse width, the first pulse width longer than the second pulse width.

22. The apparatus of claim 20, wherein the current mirror is configured to provide a first current at the first current mirror output and a second current at the second current mirror output, the first current having a different amplitude than the second current.
